(19) United States
(12) Patent Application Publication
(10) Pub. No.: US 2013/0106454 A1
(43) Pub. Date: May 2, 2013

(54) PRINTED CIRCUIT BOARD TESTING DEVICE

(71) Applicants: CHENG-TE LIU, NEW TAIPEI CITY (TW); CHING-FENG HSIEH, TAIPEI CITY (TW)

(72) Inventors: CHENG-TE LIU, NEW TAIPEI CITY (TW); CHING-FENG HSIEH, TAIPEI CITY (TW)

(73) Assignees: ASKEY COMPUTER CORP.; ASKEY TECHNOLOGY (JIANGSU) LTD.

(21) Appl. No.: 13/336,157

(22) Filed: Dec. 23, 2011

(30) Foreign Application Priority Data
Oct. 28, 2011 (TW) 100139338

(51) Int. Cl. G01R 31/20

(52) U.S. Cl. 324/750.25

(57) ABSTRACT

A printed circuit board testing device for performing an electrical test on a printed circuit board having test contacts includes a test platform, a positioning unit, an electrical connection unit, and a detecting unit. The positioning unit is disposed on the test platform and adapted to receive the printed circuit board. The electrical connection unit is disposed on the test platform and has a plurality of preset electrical functions. The electrical test specific to the test contacts is performed on the test contacts by the detecting unit connected to the test contacts and the electrical connection unit and based on the preset electrical functions.

### CROSS-REFERENCE TO RELATED APPLICATION

This non-provisional application claims priority under 35 U.S.C. §119(a) on Patent Application No(s). 100139338 filed in Taiwan, R.O.C. on Oct. 28, 2011, the entire contents of which are hereby incorporated by reference.

### FIELD OF TECHNOLOGY

The present invention relates to printed circuit board testing devices, and more particularly, to a printed circuit board testing device for performing a related electrical test on a printed circuit board having test contacts.

### BACKGROUND

According to the prior art, upon completion of a circuit layout defining process performed on a printed circuit board, it is necessary to perform an electrical test on the circuit layout on the printed circuit board for verifying whether the circuit layout enables good electrical connection efficiently.

Regarding the issue of testing a printed circuit board, related testing devices for use in testing printed circuit boards are used to being developed in accordance with a testing method. A printed circuit board intended to be tested by a related testing device comes into contact or connects to an electronic device, such as a monitor, a power supply, or a keyboard, via a connection line. Afterward, the testing device performs an electrical test on the electronic device through a plurality of test contacts disposed on the printed circuit board to determine whether the circuit layout on the printed circuit board enables the electronic device to function well. Identical printed circuit boards usually have the electronic device in common. Hence, it is feasible for the electronic device to be fixed to the testing device to facilitate an intensive session of electrical tests.

In general, to operate, the test contacts under test require an electrical signal source, such as a power input or a microphone input. The electrical signal source is generated by a dedicated circuit or component disposed on the testing device and designed to perform electrical tests on the printed circuit board.

However, the technical solution that involves generating the electrical signal source by a dedicated circuit or component is only applicable to the testing environment of a specific printed circuit board under test. Hence, the testing device cannot perform an electrical test on different printed circuit boards. The testing device has to be designed anew in order to perform the electrical test on a new printed circuit board. However, designing the testing device anew has drawbacks, that is, it requires a lengthy R&D process and incurs much production costs.

In view of the drawbacks of the prior art, the present invention puts forth a printed circuit board testing device for overcoming the drawbacks of the prior art and performing a related electrical test on printed circuit boards of any kinds.

### SUMMARY

It is an objective of the present invention to provide a printed circuit board testing device capable of selecting appropriate preset electrical functions of an electrical connection unit and performing a related electrical test directly on test contacts of a printed circuit board in accordance with the preset electrical functions.

In order to achieve the above and other objectives, the present invention provides a printed circuit board testing device for performing an electrical test on a printed circuit board having test contacts. The printed circuit board testing device comprises a test platform, a positioning unit, an electrical connection unit, and a detecting unit. The positioning unit has a receiving recess. The positioning unit is disposed on the test platform. The positioning unit receives the printed circuit board through the receiving recess. The electrical connection unit is disposed at the test platform. The electrical connection unit has a plurality of ports. The ports have preset electrical functions. The detecting unit has two testing ends, namely a testing end contactable with the test contacts, and another testing end connectable to at least one of the ports according to the electrical test to be performed on the test contacts such that the electrical test is performed on the test contacts with regard to the preset electrical functions.

A printed circuit board testing device of the present invention is equipped with the electrical connection unit having a plurality of electrical functions such that, to perform a specific preset electrical function test on a printed circuit board having a plurality of test contacts, a test worker can directly select an appropriate preset electrical function from the electrical connection unit and send the selected electrical function to the test contacts on the printed circuit board by means of the detecting unit, such that a related electrical test can be performed on the test contacts.

Regardless of the types of electrical tests to be performed on the printed circuit board, the printed circuit board testing device of the present invention is equipped with the electrical connection unit having a plurality of preset electrical functions, such that a test worker can select from the electrical connection unit an appropriate test to be performed on the printed circuit board to test the electrical functions thereof, thereby dispensing with the hassles of making a dedicated printed circuit board testing device anew for performing a specific test on the printed circuit board.

### BRIEF DESCRIPTION

Objectives, features, and advantages of the present invention are hereunder illustrated with specific embodiments in conjunction with the accompanying drawings, in which:

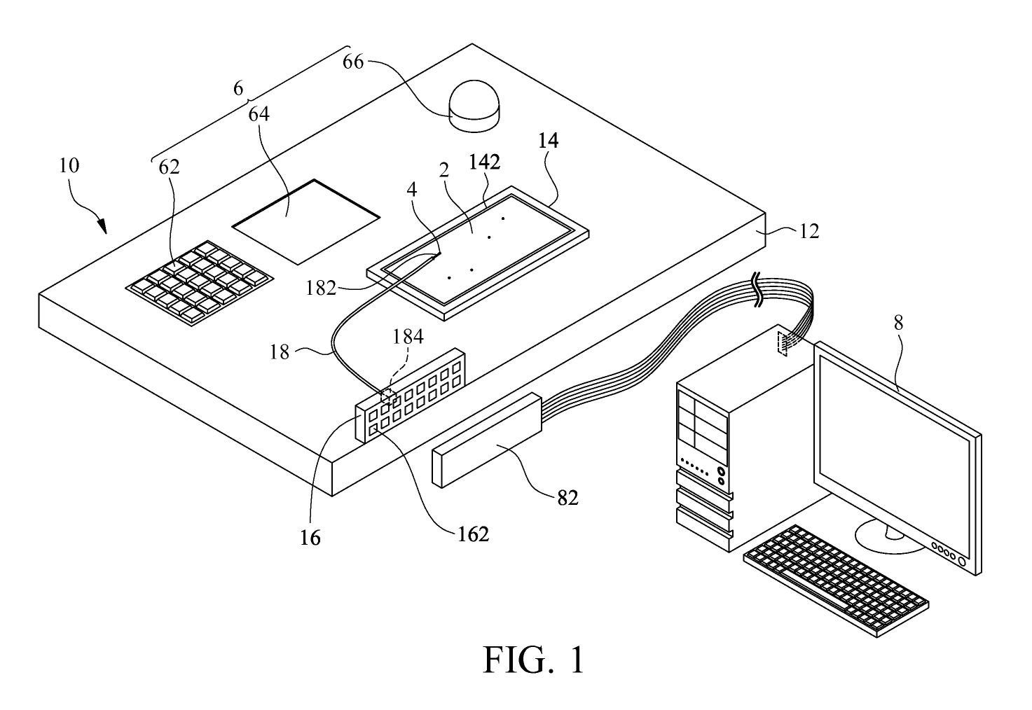

FIG. 1 is a structural schematic view of a printed circuit board testing device according to the first embodiment of the present invention;

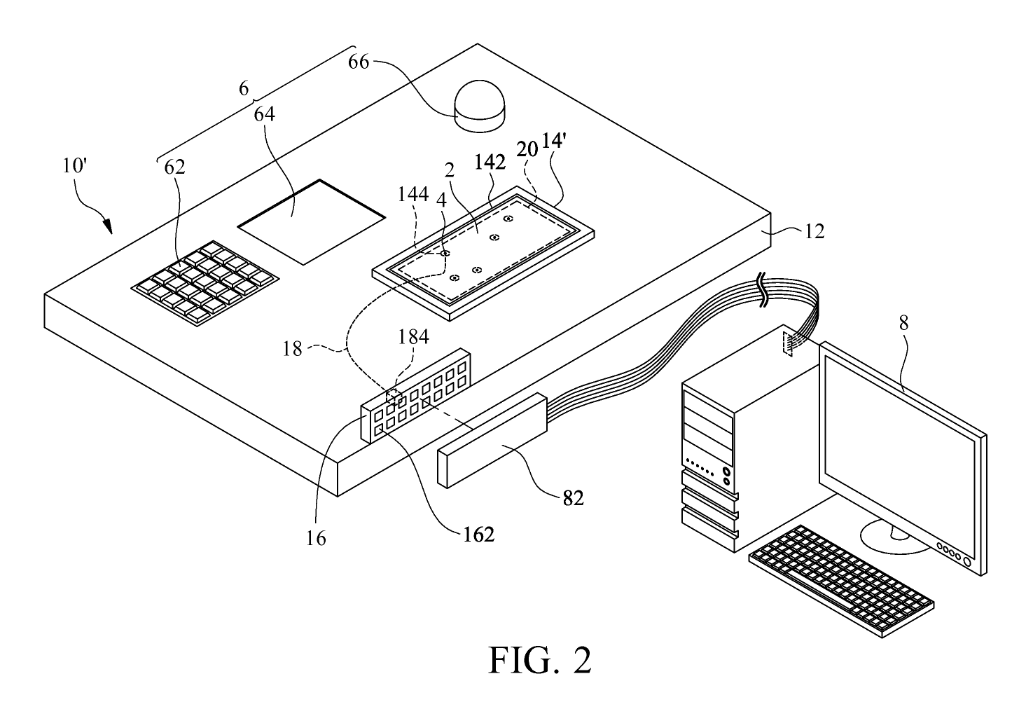

FIG. 2 is a structural schematic view of a printed circuit board testing device according to the second embodiment of the present invention; and

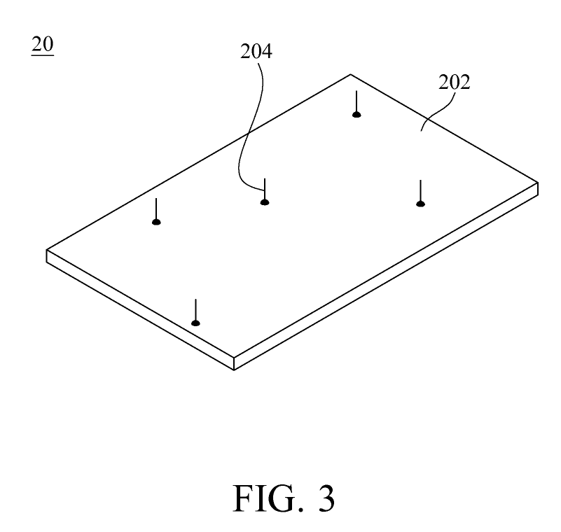

FIG. 3 is a structural schematic view of a dial module in FIG. 2.

### DETAILED DESCRIPTION

Referring to FIG. 1, there is shown a structural schematic view of a printed circuit board testing device 10 according to the first embodiment of the present invention. As shown in FIG. 1, the printed circuit board testing device 10 performs an electrical test on a printed circuit board 2. The electrical test is aimed at testing electrical features and is a voltage test, a data transmission test, a sound source test, or a display signal test. The printed circuit board 2 has a plurality of test contacts 4. The test contacts 4 are connected to an electronic device 6, such as a keyboard 62, a monitor 64, and/or a speaker 66, through the circuit layout on the printed circuit board 2.

The printed circuit board testing device 10 comprises a test platform 12, a positioning unit 14, an electrical connection unit 16, and a detecting unit 18. The positioning unit 14, the electrical connection unit 16, and the detecting unit 18 are disposed at the test platform 12.

The positioning unit 14 has a receiving recess 142 for receiving the printed circuit board 2. In the first embodiment, the test contacts 4 of the printed circuit board 2 are exposed from the receiving recess 142. In the second embodiment, the test contacts 4 of the printed circuit board 2 face the receiving recess 142, as shown in FIG. 2.

The electrical connection unit 16 has a plurality of ports 162. The ports 162 have preset electrical functions, respectively. For example, the preset electrical functions include output voltage level output, ground level output, analog power supply output, standby analog power supply output, universal serial bus (USB) input/output, RS-232 serial communication interface input/output, trigger signal output, detection input, microphone input, data input, speaker output, and earpiece input. In an embodiment, the ports 162 comprise 80 pins for supporting the preset electrical functions.

Regarding the preset electrical functions, the ports 162 are programmed through a programmable electrical input/output interface 82 disposed in a control unit 8 provided externally. For example, the control unit 8 is installed with Laboratory Virtual Instrument Engineering Workbench (Labview) for defining and configuring the preset electrical functions of the ports 162.

The detecting unit 18 has two testing ends, namely a testing end 182 and another testing end 184. The testing end 182 is in contact with the test contacts 4. The testing end 184 is connected to at least one of the ports 162, depending on the electrical test to be performed on the test contacts 4. For example, the detecting unit 18 is a single conductive wire or a bus wire. For example, if the test contacts 4 on the printed circuit board 2 need to receive a serial data, the testing end 184 of the detecting unit 18 will be connected to the ports 162 capable of RS-232 serial communication interface input/output, such that the control unit 8 can output the serial data. Furthermore, the electronic device 6 can be controlled through the test contacts 4 and a circuit layout, so as to perform electrical tests on a keyboard input, screen display, and audio output, for example.

A test worker puts the printed circuit board 2 on the test platform 12 and selects an appropriate one of the preset electrical functions from the ports 162 by means of the detecting unit 18. To enable the printed circuit board 2 to operate, it is necessary that the printed circuit board 2 is connected to the ports 162 which have access to a power supply for driving the printed circuit board 2 to operate, such that the printed circuit board 2 can receive the power required for operation. Furthermore, the power can also be supplied, through the circuit layout, to the keyboard 62, the monitor 64, and the speaker 66 connected with the printed circuit board 2. The test worker operates the keyboard 62 in a manner that, with the printed circuit board 2, a key signal is sent from the keyboard 62 to the monitor 64 and displayed on the monitor 64. An audio signal is sent from the ports 162 capable of speaker output to the speaker 66 via the test contacts 4 so as to drive the speaker 66 to operate. By carrying out the aforesaid testing operations, it is feasible to perform a related electrical test on the printed circuit board 2 so as to test the quality of the printed circuit board 2.

Regardless of the types of electrical tests to be performed on the printed circuit board 2, the printed circuit board testing device 10 of the present invention is equipped with the electrical connection unit 16 having a plurality of preset electrical functions, such that the test worker can select from the electrical connection unit 16 an appropriate test to be performed on the printed circuit board 2 to test the electrical functions thereof, thereby dispensing with the hassles of making a dedicated printed circuit board testing device anew for performing a specific test on the printed circuit board 2.

Referring to FIG. 2, there is shown a structural schematic view of a printed circuit board testing device according to the second embodiment of the present invention. As shown in FIG. 2, a printed circuit board testing device 10′ comprises the test platform 12, the positioning unit 14′, the electrical connection unit 16, and the detecting unit 18. The second embodiment is different from the first embodiment in that, in the second embodiment, the positioning unit 14′ further comprises at least a through hole 144. The at least a through hole 144 is disposed at the receiving recess 142. The at least a through hole 144 corresponds in position to the test contacts 4. The test contacts 4 of the printed circuit board 2 face the receiving recess 142, such that the detecting unit 18 is electrically connected to the test contacts 4 through the at least a through hole 144.

The printed circuit board testing device 10′ further comprises a dial module 20. The dial module 20 comprises a plate 202 and needles 204. The dial module 20 is selectively disposed between the test platform 12 and the positioning unit 14. That is to say, the dial module 20 is replaceable such that the dial module 20 suits and applies to a printed circuit board having various test contacts. For example, the detecting unit 18 is electrically connected to the dial module 20 in advance, such that the needles 204 on the dial module 20 can penetrate the at least a through hole 144 in the receiving recess 142 to abut against the test contacts 4 of the printed circuit board 2, thereby allowing a related electrical test to be performed on the printed circuit board 2. The dial module 20 is shown in FIG. 3.

Hence, a printed circuit board testing device of the present invention is equipped with ports having a plurality of electrical functions such that, to perform a specific preset electrical function test on a printed circuit board, a test work can select appropriate preset electrical characteristics from the ports having the electrical functions and directly perform a related electrical test on test contacts on the printed circuit board.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A printed circuit board testing device for performing an electrical test on a printed circuit board having test contacts, comprising:
a test platform;
a positioning unit having a receiving recess, disposed on the test platform, and adapted to receive the printed circuit board through the receiving recess;
an electrical connection unit disposed at the test platform and having a plurality of ports, wherein the ports have preset electrical functions, respectively; and
a detecting unit having two testing ends, one contactable with the test contacts, another connectable to at least one of the ports according to the electrical test to be performed on the test contacts, such that the electrical test is performed on the test contacts with regard to the preset electrical functions.

2. The printed circuit board testing device of claim 1, further comprising a control unit having a programmable electrical input/output interface and connected to the electrical connection unit for controlling the preset electrical functions of the ports through the programmable electrical input/output interface.

3. The printed circuit board testing device of claim 2, wherein the control unit is installed with Laboratory Virtual Instrument Engineering Workbench.

4. The printed circuit board testing device of claim 2, wherein the preset electrical functions include at least one of output voltage level output, ground level output, analog power supply output, standby analog power supply output, universal serial bus (USB) input/output, RS-232 serial communication interface input/output, trigger signal output, detection input, microphone input, data input, speaker output, and earpiece input.

5. The printed circuit board testing device of claim 1, wherein the detecting unit is one of a single conductive wire and a bus wire.

6. The printed circuit board testing device of claim 1, wherein the ports comprise 80 pins.

7. The printed circuit board testing device of claim 1, wherein the positioning unit further comprises at least a through hole disposed at the receiving recess and corresponding in position to the test contacts.

8. The printed circuit board testing device of claim 7, further comprising a dial module having a plate and needles and being selectively disposed between the test platform and the positioning unit, the needles corresponding in position to the at least a through hole and penetrating the at least a through hole to come into contact with the test contacts.
